(19) United States
(12) Patent Application Publication
(10) Pub. No.: US 2024/0420005 A1
(43) Pub. Date: Dec. 19, 2024

(54) GRID ARCHITECTURE FOR CONTROLLING LARGE SCALE QUANTUM PROCESSORS

(71) Applicant: Anyon Computing Inc., Emeryville, CA (US)

(72) Inventors: Jie Luo, Emeryville, CA (US); Hengjiang Ren, Emeryville, CA (US); Xinyu Liu, Emeryville, CA (US)

(21) Appl. No.: 18/738,600

(22) Filed: Jun. 10, 2024

Related U.S. Application Data
(60) Provisional application No. 63/508,926, filed on Jun. 19, 2023.

(51) Int. Cl. G06N 10/40; H03K 17/92

(52) U.S. Cl. CPC G06N 10/40; H03K 17/92

(57) ABSTRACT

A controller for a set of superconducting qubits includes a parametrically driven tunable coupler coupled to each superconducting qubit in the set of superconducting qubits comprising three or more superconducting qubits, a magnetic flux pump coupled to the parametrically driven tunable coupler, a first control line coupled to the magnetic flux pump, and a second control line coupled to the magnetic flux pump. The parametrically driven tunable coupler creates a parametric single superconducting qubit drive for a single superconducting qubit within the set of superconducting qubits or a parametric resonant interaction between a pair of superconducting qubits within the set of superconducting qubits when one or more first frequency signals on the first control line and one or more second frequency signals on the second control line satisfy a specified condition.

### CROSS-REFERENCE TO RELATED APPLICATIONS

This application claims priority to U.S. Provisional Application Ser. No. 63/508,926 filed Jun. 19, 2023 entitled “Grid Architecture for Controlling Large Scale Quantum Processors”. The entire contents of the foregoing application is incorporated herein by reference.

### STATEMENT OF FEDERALLY FUNDED RESEARCH

Not applicable.

### TECHNICAL FIELD OF THE INVENTION

The present disclosure relates in general to processors. In particular, the present disclosure relates to a grid architecture for controlling large scale quantum processors.

### BACKGROUND OF THE INVENTION

Current methods to implement full control of all individual superconducting qubits and coupling between superconducting qubits demand individual physical control lines to address each superconducting qubit and each coupling between two superconducting qubits. Such traditional and commonly used architecture significantly increases the difficulty of creating low-crosstalk, low-error quantum processors as they inevitably require the number of control lines to scale with the number of superconducting qubits and couplings. For example, considering a common square grid arrangement of N\hat{ }2 superconducting qubits on a superconducting quantum processor with each superconducting qubit coupled to four nearest neighbors directly, full control of this quantum processor demands at least N\hat{ }2 single superconducting qubit control lines to each superconducting qubit and 2*N\hat{ }2−2*(4*N−4) control lines for couplings between coupled superconducting qubit pairs. Moreover, to access the interior superconducting qubits of the N×N superconducting qubit grid in the above typical example, control wires will inevitably crossover each other and even superconducting qubits, which significantly increases crosstalk, superconducting qubit control errors, as well as decoherence noise channels for superconducting qubits. To mitigate such errors and noises, sophisticated methods in micro-fabrication and quantum control optimization algorithms have been explored extensively. The mitigation methods not only significantly increased the difficulty of scaling quantum processors beyond the current scale but also questionable in whether such mitigation methods are themselves scalable (i.e., such methods are potentially unsustainable to fix issues for large-scale quantum processors since scaling these methods become difficult as QPU size increases).

### SUMMARY OF THE INVENTION

One embodiment of the present disclosure provides a controller for a set of superconducting qubits that includes a parametrically driven tunable coupler coupled to each superconducting qubit in the set of superconducting qubits comprising three or more superconducting qubits, a magnetic flux pump coupled to the parametrically driven tunable coupler, a first control line coupled to the magnetic flux pump, and a second control line coupled to the magnetic flux pump. The parametrically driven tunable coupler creates a parametric single superconducting qubit drive for a single superconducting qubit within the set of superconducting qubits or a parametric resonant interaction between a pair of superconducting qubits within the set of superconducting qubits when one or more first frequency signals on the first control line and one or more second frequency signals on the second control line satisfy a specified condition.

In one aspect, a readout resonator is coupled to each superconducting qubit in the set of superconducting qubits. In another aspect, each superconducting qubit in the set of superconducting qubits is configured to respond to a specified frequency from the parametrically driven tunable coupler. In another aspect, the set of superconducting qubits are arranged around each parametrically driven tunable coupler. In another aspect, the parametrically driven tunable coupler includes a superconducting quantum interface device (SQUID). In another aspect, the first control line and the second control line intersect at a flux control port location of the parametrically driven tunable coupler. In another aspect, the specified condition comprises a sum or difference of the one or more first frequency signals and the one or more second frequency signals that correspond to the pair of superconducting qubits, and the specified condition comprises a sum or difference of the one or more first frequency signals, the one or more second frequency signals and a dipole drive signal that correspond to the single superconducting qubit. In another aspect, the pair of superconducting qubits comprises Q!/(2!*(Q−2)!) pairwise combinations for the set of three or more superconducting qubits, where Q is a number of superconducting qubits in the set of three or more superconducting qubits. In another aspect, the set of superconducting qubits, the parametrically driven tunable coupler, and the magnetic flux pump are disposed on a first chip, the first control line and the second control line are disposed on a second chip, and the first chip and the second chip are bonded together in a flip-chip configuration.

Another embodiment of the present disclosure provides a quantum processor that includes an array of superconducting qubits arranged in sets of three or more superconducting qubits, and a controller coupled to each set of three or more superconducting qubits. The controller includes a parametrically driven tunable coupler coupled to each superconducting qubit in the set of three or more superconducting qubits, a magnetic flux pump coupled to the parametrically driven tunable coupler, a first control line coupled to the magnetic flux pump, and a second control line coupled to the magnetic flux pump. The parametrically driven tunable coupler creates a parametric single superconducting qubit drive for a single superconducting qubit within the set of three or more superconducting qubits or a parametric resonant interaction between a pair of superconducting qubits within the set of three or more superconducting qubits when one or more first frequency signals on the first control line and one or more second frequency signals on the second control line satisfy a specified condition.

In one aspect, a number of superconducting qubits in the array of superconducting qubits scales at N×M while a total number of the first control lines and the second control lines scales at N+M. In another aspect, a readout resonator is coupled to each superconducting qubit in the set of three or more superconducting qubits. In another aspect, each superconducting qubit in the set of three or more superconducting qubits is configured to respond to a specified frequency from the parametrically driven tunable coupler. In another aspect, the parametrically driven tunable couplers are arranged in a square lattice, a rectangular lattice, an oblique lattice, a hexagonal lattice or a rhombic lattice with the three or more superconducting qubits arranged around each parametrically driven tunable coupler. In another aspect, the parametrically driven tunable coupler includes a superconducting quantum interface device (SQUID). In another aspect, the first control line and the second control line intersect at a flux control port location of the parametrically driven tunable coupler. In another aspect, the specified condition comprises a sum or difference of the one or more first frequency signals and the one or more second frequency signals that correspond to the pair of superconducting qubits, and the specified condition comprises a sum or difference of the one or more first frequency signals, the one or more second frequency signals and a dipole drive signal that correspond to the single superconducting qubit. In another aspect, the pair of superconducting qubits comprises Q!/(2!*(Q−2)!) pairwise combinations for the set of three or more superconducting qubits, where Q is a number of superconducting qubits in the set of three or more superconducting qubits. In another aspect, the set of superconducting qubits, the parametrically driven tunable coupler, and the magnetic flux pump are disposed on a first chip, the first control line and the second control line are disposed on a second chip, and the first chip and the second chip are bonded together in a flip-chip configuration.

Another embodiment of the present disclosure provides a method of controlling a set of superconducting qubits by providing a parametrically driven tunable coupler coupled to each superconducting qubit in the set of superconducting qubits, a magnetic flux pump coupled to the parametrically driven tunable coupler, a first control line coupled to the magnetic flux pump, and a second control line coupled to the magnetic flux pump, transmitting one or more first frequency signals on the first control line and one or more second frequency signals on the second control line, and creating, using the parametrically driven tunable coupler, a parametric single superconducting qubit drive for a single superconducting qubit within the set of superconducting qubits or a parametric resonant interaction between a pair of superconducting qubits within the set of superconducting qubits when the one or more first frequency signals and the one or more second frequency signals satisfy a specified condition.

In one aspect, the set of superconducting qubits comprises three or more superconducting qubits. In another aspect, a readout resonator is coupled to each superconducting qubit in the set of superconducting qubits. In another aspect, each superconducting qubit in the set of superconducting qubits is configured to respond to a specified frequency from the parametrically driven tunable coupler. In another aspect, the set of superconducting qubits are arranged around each parametrically driven tunable couple. In another aspect, the parametrically driven tunable coupler includes a superconducting quantum interface device (SQUID). In another aspect, the first control line and the second control line intersect at a flux control port location of the parametrically driven tunable coupler. In another aspect, the specified condition comprises a sum or difference of the one or more first frequency signals and the one or more second frequency signals that correspond to the pair of superconducting qubits, and the specified condition comprises a sum or difference of the one or more first frequency signals, the one or more second frequency signals and a dipole drive signal that correspond to the single superconducting qubit. In another aspect, the pair of superconducting qubits comprises Q!/(2!*(Q−2)!) pairwise combinations for the set of three or more superconducting qubits where Q is a number of superconducting qubits in the set of three or more superconducting qubits.

### BRIEF DESCRIPTION OF THE DRAWINGS

For a more complete understanding of the features and advantages of the present disclosure, reference is now made to the detailed description of the disclosure along with the accompanying figures, in which:

FIG. 1 depicts a quantum processor in accordance with one embodiment of the present disclosure;

FIG. 2 is a microscopic photograph of two superconducting qubits, one superconducting qubit's readout resonator, and two parametrically driven tunable couplers within the quantum processor of FIG. 1 in accordance with one embodiment of the present disclosure;

FIG. 3 depicts an expanded view of a set of superconducting qubits within the quantum processor of FIG. 1 in accordance with one embodiment of the present disclosure;

FIG. 4 depicts an expanded view of a parametrically driven tunable coupler within the quantum processor of FIG. 1 in accordance with one embodiment of the present disclosure;

FIG. 5 depicts an expanded view of a set of a superconducting qubit within the quantum processor of FIG. 1 in accordance with one embodiment of the present disclosure;

FIG. 6 depicts a flip-chip configuration in accordance with one embodiment of the present disclosure;

FIGS. 7A and 7B depict a parametric single superconducting qubit drive in accordance with one embodiment of the present disclosure;

FIGS. 8A and 8B depict a parametric two superconducting qubit interaction in accordance with one embodiment of the present disclosure;

FIGS. 9A and 9B depict quantum processors having a set of three superconducting qubits in accordance with one embodiment of the present disclosure; and

FIG. 10 depicts a method of controlling a set of superconducting qubits in accordance with one embodiment of the present disclosure.

### DETAILED DESCRIPTION OF THE INVENTION

Illustrative embodiments of the system of the present application are described below. In the interest of clarity, not all features of an actual implementation are described in this specification. It will of course be appreciated that in the development of any such actual embodiment, numerous implementation-specific decisions must be made to achieve the developer's specific goals, such as compliance with system-related and business-related constraints, which will vary from one implementation to another. Moreover, it will be appreciated that such a development effort might be complex and time-consuming but would nevertheless be a routine undertaking for those of ordinary skill in the art having the benefit of this disclosure.

The present disclosure paves way for scaling up quantum processors by significantly reducing the number of control lines required as traditional technologies require control lines scaling approximately as O(N) where N is the total number of superconducting qubits while our disclosure only requires O(\sqrt{N}). Such fundamental scaling advantage also significantly reduces the need for sophisticated micro-fabrication technologies and advanced quantum control optimization algorithms for implementing and operating large-scale (large number of superconducting qubit) quantum processors with high connectivity (high coordination number). As large-scale quantum processors and their controls will bring together the so-called quantum advantage in computational solutions to key problems in discovering/creating new materials, medicine, AI, etc. The present disclosure, by providing a scalable architecture for large-scale quantum processor, will potentially be the key to accelerating unlocking the next evolution of information technology and a new era with abundant market opportunities.

Various embodiments of the present disclosure provide a number of advantages. While traditional methods for controlling N×M superconducting qubits having coordination number c in a N×M grid require approximately N*M+c*N*M/2 control lines to address all superconducting qubits and their couplings, the architecture disclosed herein simplifies the number of control lines to scale as N+M. This advantage significantly reduces the micro-fabrication and quantum control algorithm optimization requirements to mitigate errors and noises that arise from control lines crossing over each other and superconducting qubits. The present disclosure allows direct high-fidelity addressing of high connectivity (coordination number) of large N*M superconducting qubit array in a N-by-M rectangle grid. The architecture disclosed herein improves the scalability of superconducting quantum processors.

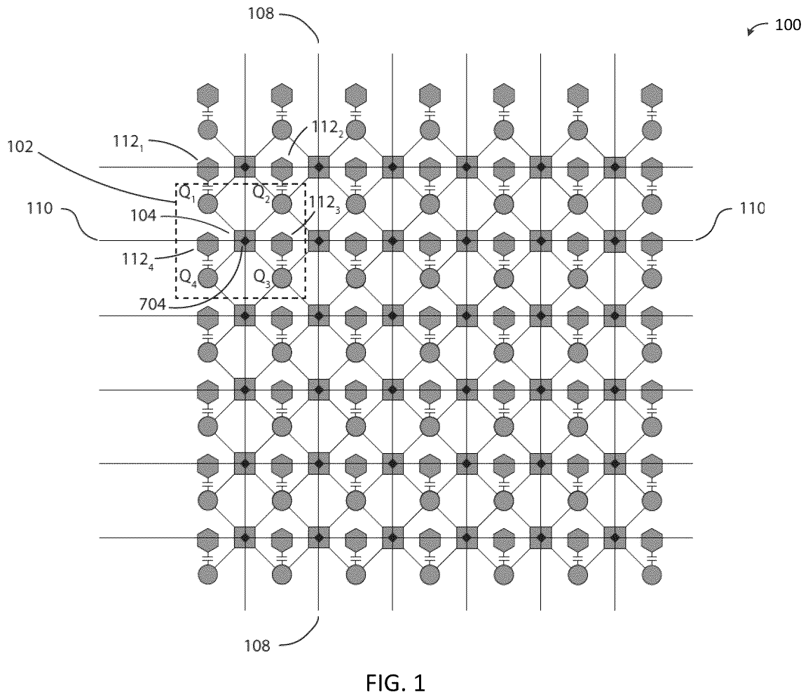

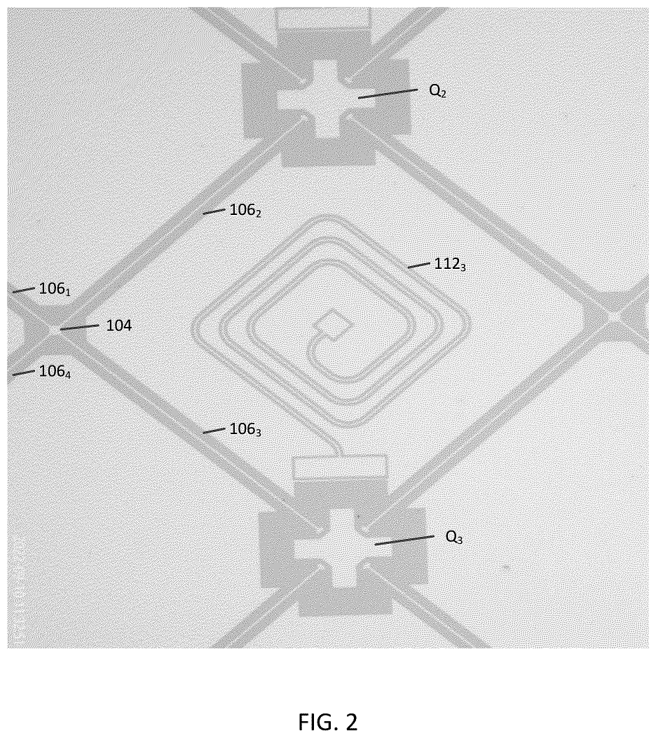

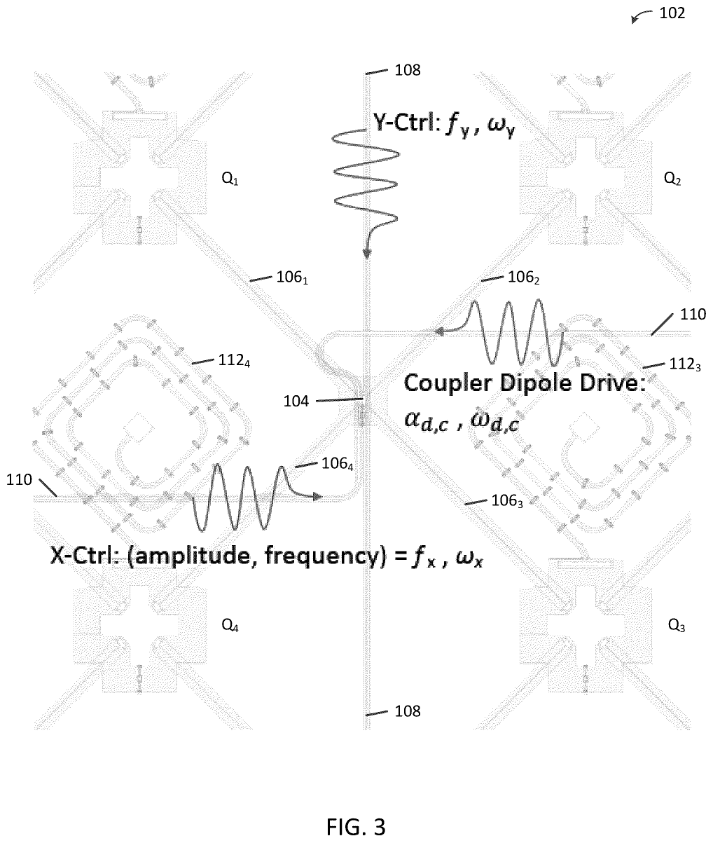

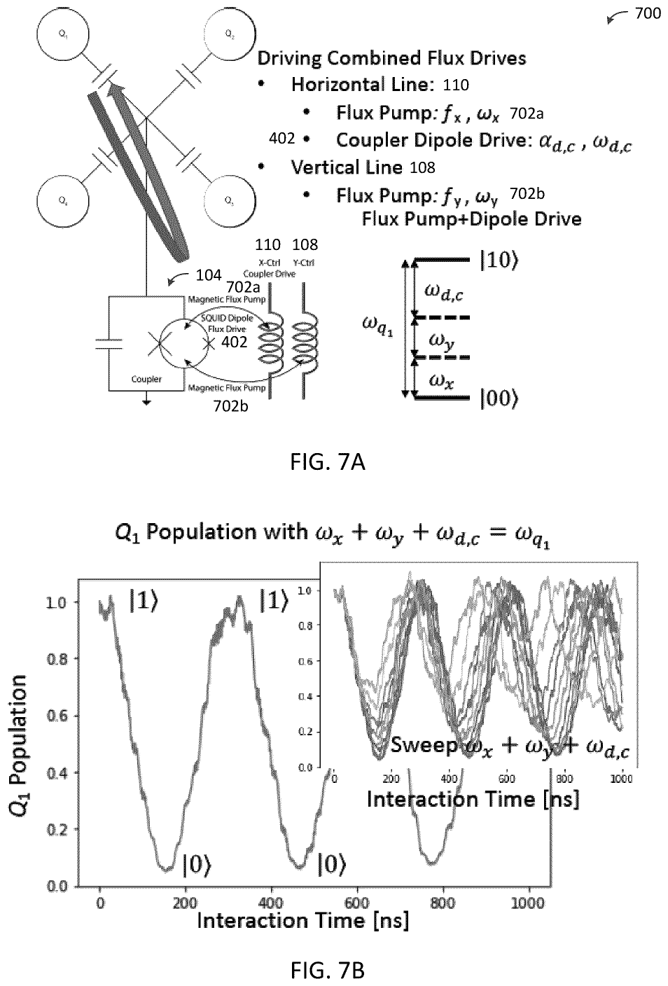

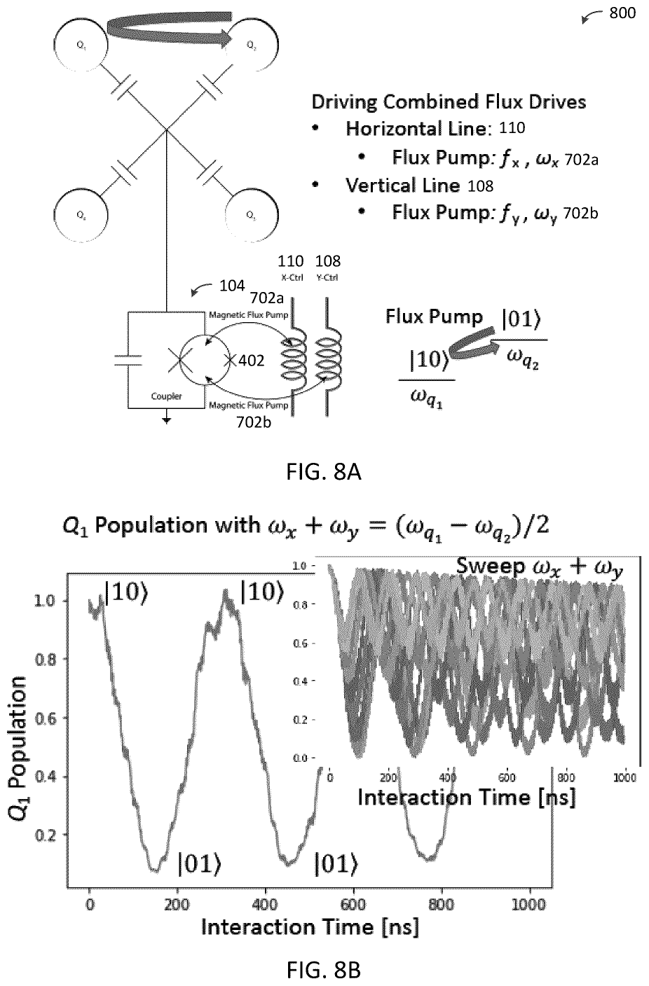

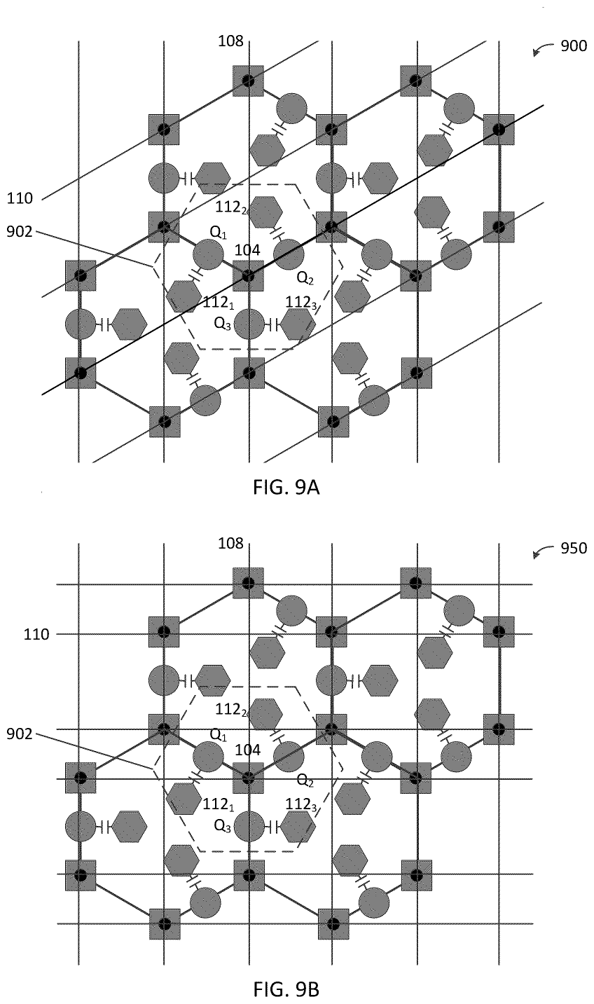

Now referring to FIG. 1, a quantum processor 100 in accordance with one embodiment of the present disclosure is shown. Also referring to FIGS. 2 and 3, various details of the quantum processor 100 are shown. The quantum processor 100 includes an array of superconducting qubits arranged in sets of three or more superconducting qubits (e.g., 102). In this example, there are four superconducting qubits Q₁, Q₂, Q₃, Q₄ in the set of superconducting qubits 102. Examples of a set of superconducting qubits having three superconducting qubits are shown in FIGS. 9A and 9B. The set of superconducting qubits can include more than three or four superconducting qubits. A parametrically driven tunable coupler 104 is coupled to each superconducting qubit Q₁, Q₂, Q₃, Q₄ in the set of superconducting qubits 102 via connectors 106₁, 106₂, 106₃, 106₄. More specifically, the parametrically driven tunable couplers 104 within the quantum processor 100 are arranged in a square lattice with the three or more superconducting qubits arranged around each parametrically driven tunable coupler 104. Note that a rectangular lattice, an oblique lattice, a hexagonal lattice, a rhombic lattice, or other geometric-shaped lattice can be used. The parametrically driven tunable coupler 104 includes magnetic flux pumps 702a, 702b that are coupled to a first control line 108 and a second control line 110 intersecting a flux control port location 704. (see FIGS. 7A and 8A). In this example, the first control line 108 is a vertical control line (Y-Ctrl), and the second control line 110 is a horizontal control line (X-Ctrl). As illustrated in FIG. 6, the control lines 108 and 110 can be located on a separate silicon chip “wire-chip” such that the qubit-chip dies are flip-chip bonded to the wire-chip. For a N-by-M superconducting qubit array, the total number of the first control lines 108 and the second control lines 110 scales at N+M (i.e., one-half the circumference of the array) as the number of qubits in the array scale as N×M, which is a significant improvement over the prior art scaling of N×M (i.e., the total number of qubits in the array). Other than the stated scaling law advantage, more or fewer first and second control lines 108, 110 can be used depending on the actual requirements of specific designs. Each superconducting qubit Q₁, Q₂, Q₃, Q₄ includes a superconducting qubit readout resonator 112₁, 112₂, 112₃, 112₄. The parametrically driven tunable coupler 104 creates a parametric single superconducting qubit drive for a single superconducting qubit within the set of superconducting qubits 102 (see FIGS. 7A and 7B) or a parametric resonant interaction between a pair of superconducting qubits within the set of superconducting qubits 102 (see FIGS. 8A and 8B) when one or more first frequency signals on the first control line 108 and one or more second frequency signals on the second control line 110 satisfy a specified condition. In this example, the pair of superconducting qubits can be one of six pairwise combinations: Q₁-Q₂, Q₁-Q₃, Q₁-Q₄, Q₂-Q₃, Q₂-Q₄, Q₃-Q₄. In other embodiments, the pair of superconducting qubits are Q!/(2!*(Q−2)!) pairwise combinations for the set of three or more superconducting qubits where Q is a number of superconducting qubits in the set of three or more superconducting qubits.

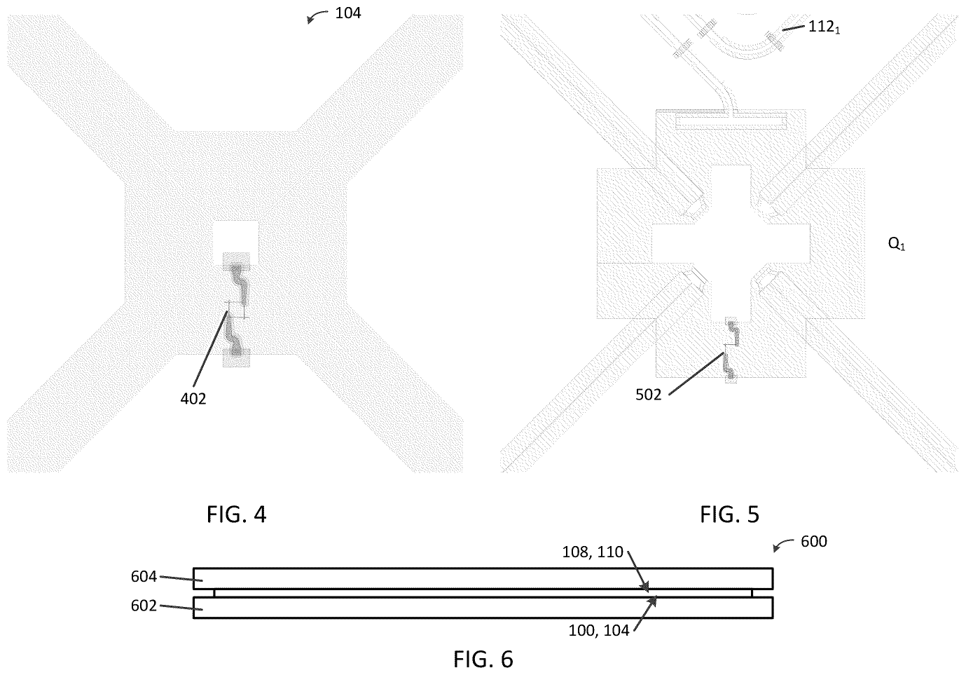

As shown in FIG. 3, the parametrically driven tunable coupler 104 provides frequency-spatial selectivity. The first control line 108 provides one or more first frequency signals having a non-zero amplitude f_{y} and a frequency ω_{y}. The second control line 110 provides one or more second frequency signals having a non-zero amplitude fₓ and a frequency ωₓ. The desired parametrically driven tunable coupler 104 is at the intersection of certain control lines (X-Ctrl, Y-Ctrl) carrying signals of non-zero amplitudes (fₓ,f_{y}). The desired interaction occurs when the two control frequencies (ωₓ,ω_{y}) satisfy certain conditions. The parametrically driven tunable coupler 104 is also driven by a parametric dipole drive signal having amplitude α_{d,c} and frequency ω_{d,c} on either control line 108 and/or 110. The complied effect is an effective parametric dipole drive on a single superconducting qubit coupled to the parametrically driven tunable coupler 104 when specific conditions between the three control driving signals are met (i.e., two control signals and the dipole drive signal. (see FIGS. 4, 7A and 7B).

Referring now to FIG. 4, an expanded view of a parametrically driven tunable coupler 104 within the quantum processor 100 of FIG. 1 in accordance with one embodiment of the present disclosure is shown. The parametrically driven tunable coupler 104 may include a superconducting quantum interface device (SQUID) 402. An asymmetric SQUID 402 will lead to a driven dipole term in the dynamics of the driven tunable coupler-superconducting qubit system. The dipole drive interaction is inducted by the flux drive signals on the two intersecting control lines 108, 110 when specific conditions between the signals are met.

Now referring to FIG. 5, an expanded view of a set of a superconducting qubit Q₁ within the quantum processor 100 of FIG. 1 in accordance with one embodiment of the present disclosure is shown. Each superconducting qubit, e.g., Q₁, includes a single Josephson junction 502 that is used to tune the superconducting qubit to a fixed frequency. Detailed non-limiting examples of various aspects of superconducting qubits are described in PCT Patent Application serial number PCT/US23/19199 filed on Apr. 20, 2023, U.S. patent application Ser. No. 18/137,016 filed on Apr. 20, 2023, U.S. Provisional Patent Application Ser. No. 63/426,204 filed on Nov. 17, 2022, and U.S. Provisional Patent Application Ser. No. 63/333,225 filed on Apr. 21, 2022, all of which are hereby incorporated by reference in their entirety.

Referring now to FIG. 6, a flip-chip configuration 600 in accordance with one embodiment of the present disclosure. The array of superconducting qubits and the parametrically driven tunable couplers 104 are disposed on a first chip 602, and the first control lines 108 and the second control lines 110 are disposed on a second chip 604. The first chip 602 and the second chip 604 are bonded together in the flip-chip configuration 600.

Now referring to FIGS. 7A and 7B, a parametric single superconducting qubit drive 700 in accordance with one embodiment of the disclosure is shown. A two-tone parametric flux pump 702a-702b is coupled to the parametrically driven tunable coupler 104 and is used to create parametric single superconducting qubit drive for superconducting qubits coupled to the coupler. In the embodiment shown, four superconducting qubits Q₁, Q₂, Q₃, Q₄ are connected to each parametrically driven tunable coupler 104. More superconducting qubits can be connected to each parametrically driven tunable coupler 104. Parametric coupling processes supported by one parametrically driven tunable coupler 104 are activated by two orthogonal control lines 108, 110 intersecting the flux control port location, which is a geometric structure above the SQUID 402. The flux control port location couples the driving signals from the two control lines 108, 110 into the SQUID 402 generating a parametric drive on the parametrically driven tunable coupler 104 and creating driven parametric interaction between the single superconducting qubit drive as described above. The parametrically driven tunable coupler 104 is tunable by the magnetic flux through the SQUID 402. These two intersecting control lines 108, 110 should each carry one or more frequency tones such that the sum or difference between the frequency tones correspond to appropriate values corresponding to one desired type of single superconducting qubit drive for one desired superconducting qubit. Similar to above, such dual selection rule enables precise control of single superconducting qubit drive to happen precisely only as intended and minimizes the quantum control errors for implementing precise gates for a single superconducting qubit.

The driving combined flux drives for the horizontal control line 110 are the magnetic flux pump 702a (fₓ, ωₓ) and the SQUID dipole drive pump 402 (α_{d,c}, ω_{d,c}). The driving combined flux drives for the vertical control line 108 are the magnetic flux pump 702b (f_{y}, ω_{y}) and potentially SQUID dipole drive pump 402 (α_{d,c}, ω_{d,c}). Thus in this example, the single superconducting qubit drive condition for Q₁ with 0-1 transition frequency ω_{q}_{₁} is ωₓ+ω_{y}+ω_{d,c}≈ω_{q}_{₁}, which is illustrated versus interaction time in nanoseconds in the graph of FIG. 7B. In the demonstration, the Q₁ state is initialized to |1>. The Even-Wave Mixing Hamiltonian after renormalization [1,2] static superconducting qubit interactions is:

Hᵢₙₜ=Eⱼ cos(fₓ sin ωₓt+f_{y} sin ω_{y}t)cos(φ_{q}_{₁}+φ_{q}_{₂}+φ_{q}_{₃}+φ_{q}_{₄}+φ_{c})+α_{d,c} sin(ω_{d,c}t)φ_{c}.

The Even-Wave Mixing Hamiltonian for the asymmetric SQUID 402 with asymetry parameter d creating the dipole drive term as the last term of the above interaction Hamiltonian is:

$${H}_{f , d} = {E}_{j} d sin ( {f}_{d , c} sin {ω}_{d , c} t ) sin {φ}_{c} .$$

Referring now to FIGS. 8A and 8B, a parametric two superconducting qubit interaction 800 in accordance with one embodiment of the disclosure is shown. A two-tone parametric flux pump 702 is coupled to the parametrically driven tunable coupler 104 and is used to create parametric resonant interactions between desired superconducting qubit pairs coupled to the coupler. In one embodiment, four superconducting qubits Q₁, Q₂, Q₃, Q₄ are connected to each coupler. More superconducting qubits can be connected to each parametrically driven tunable coupler 104. Parametric coupling processes supported by one parametrically driven tunable coupler 104 are activated by two orthogonal control lines 108, 110 intersecting the flux control port location, which is a geometric structure above the SQUID 402. The flux control port location couples the driving signals from the two control lines 108, 110 into the SQUID 402 generating a parametric drive on the parametrically driven tunable coupler 104 and creating driven parametric interaction between the pair of superconducting qubits as described above. These two intersecting control lines 108, 110 should each carry one or more frequency tones such that the sum or difference between the frequency tones correspond to appropriate values corresponding to one type of two superconducting qubit couplings between two superconducting qubits coupled to the shared driven coupler. The pair of superconducting qubits can be one of six pairwise combinations: Q₁-Q₂, Q₁-Q₃, Q₁-Q₄, Q₂-Q₃, Q₂-Q₄, Q₃-Q₄. In other embodiments, the pair of superconducting qubits are Q!/(2!*(Q−2)!) pairwise combinations for the set of three or more superconducting qubits where Q is a number of superconducting qubits in the set of three or more superconducting qubits. Thus, in summary, simultaneous spatial and spectral selection of desired parametric interactions between desired superconducting qubit pairs implement desired two-superconducting qubit gates. Such dual selection rule enables precise control of qubit-qubit interactions to happen precisely only as intended and minimizes the quantum control errors for implementing precise gates between superconducting qubits.

As mentioned above, multi-tone drives are used to activate and apply desired precision quantum controls for single-qubits and qubit pairs. Such tones can be multiplexed in frequency on the two intersecting control lines for creating desired interactions and drives on superconducting qubits sharing one coupler. Also, spatial control multiplexing is also possible to activate two superconducting qubit interactions along a chain by simultaneously drive several intersecting control lines.

The driving combined flux drives for the horizontal control line 110 is the magnetic flux pump 702a (fₓ, ωₓ). The driving combined flux drives for the vertical control line 108 is the magnetic flux pump 702b (f_{y}, ω_{y}). Thus in this example, the parametric photon exchange condition for Q₁ with stationary frequency ω_{q}_{₁} and Q₂ with stationary frequency ω_{q}_{₂} is ωₓ+ω_{y}≈(ω_{q}_{₁}−ω_{q}_{₂})/2, which is illustrated versus interaction time in nanoseconds in the graph of FIG. 8B. The |Q₁ Q₂> system is initialized with |10>. The Even-Wave Mixing Hamiltonian after renormalization [1,2] static superconducting qubit coupler interactions is:

$${H}_{int} = {E}_{j} cos ( {f}_{x} sin {ω}_{x} t + {f}_{y} sin {ω}_{y} t ) cos ( {φ}_{{q}_{1}} + {φ}_{{q}_{2}} + {φ}_{{q}_{3}} + {φ}_{{q}_{4}} + {φ}_{c} ) .$$

Now referring to FIG. 9A, a quantum processor 900 having a set of three superconducting qubits 902 in accordance with one embodiment of the present disclosure are shown. A parametrically driven tunable coupler 104 is coupled to each superconducting qubit Q₁, Q₂, Q₃ in the set of superconducting qubits 902 via connectors. More specifically, the parametrically driven tunable couplers 104 within the quantum processor 900 are arranged in a hexagonal lattice with the three superconducting qubits Q₁, Q₂, Q₃ arranged around each parametrically driven tunable coupler 104. The parametrically driven tunable coupler 104 includes a magnetic flux pump that is coupled to a first control line 108 and a second control line 110 intersecting a flux control port location. (see FIGS. 7A and 8A). In this example, the first control line 108 is a vertical control line (Y-Ctrl), and the second control line 110 is a diagonal control line (D-Ctrl).

Referring now to FIG. 9B, a quantum processor 950 having a set of three superconducting qubits 902 in accordance with one embodiment of the present disclosure are shown. A parametrically driven tunable coupler 104 is coupled to each superconducting qubit Q₁, Q₂, Q₃ in the set of superconducting qubits 902 via connectors. More specifically, the parametrically driven tunable couplers 104 within the quantum processor 950 are arranged in a hexagonal lattice with the three superconducting qubits Q₁, Q₂, Q₃ arranged around each parametrically driven tunable coupler 104. The parametrically driven tunable coupler 104 includes a magnetic flux pump that is coupled to a first control line 108 and a second control line 110 intersecting a flux control port location. (see FIGS. 7A and 8A). In this example, the first control line 108 is a vertical control line (Y-Ctrl), and the second control line 110 is a horizontal control line (X-Ctrl).

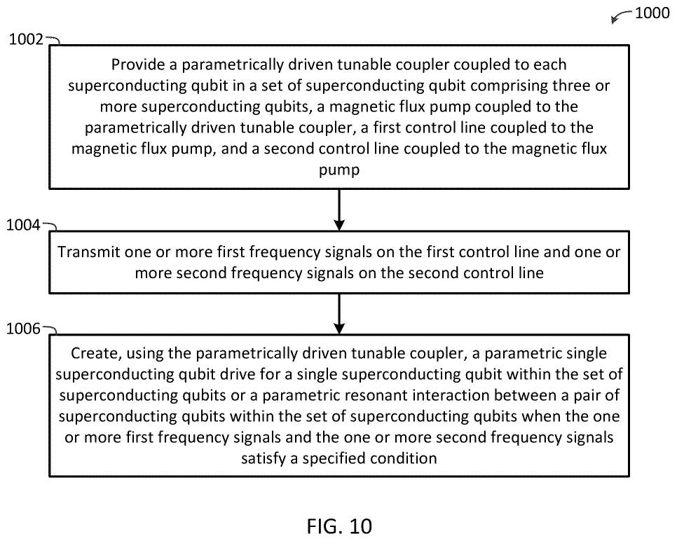

Referring now to FIG. 10, a method 1000 for controlling a set of superconducting qubits in accordance with one embodiment of the present disclosure is shown.

A parametrically driven tunable coupler coupled to each superconducting qubit in the set of superconducting qubits comprising three or more superconducting qubits, a magnetic flux pump coupled to the parametrically driven tunable coupler, a first control line coupled to the magnetic flux pump, and a second control line coupled to the magnetic flux pump are provided in block 1002. One or more first frequency signals are transmitted on the first control line and one or more second frequency signals are transmitted on the second control line in block 1004. Using the parametrically driven tunable coupler, a parametric single superconducting qubit drive for a single superconducting qubit within the set of superconducting qubits or a parametric resonant interaction between a pair of superconducting qubits within the set of superconducting qubits is created when the one or more first frequency signals and the one or more second frequency signals satisfy a specified condition in block 1006.

In one aspect, a readout resonator is coupled to each superconducting qubit in the set of superconducting qubits. In another aspect, each superconducting qubit in the set of superconducting qubits is configured to respond to a specified frequency from the parametrically driven tunable coupler. In another aspect, the set of superconducting qubits are arranged around each parametrically driven tunable couple. In another aspect, the parametrically driven tunable coupler includes a superconducting quantum interface device (SQUID) with asymmetry parameter d for realizing flux tunable coupling between the superconducting qubits and generating qubit-qubit parametric coupling as well as single superconducting qubit dipole driving. In another aspect, the first control line and the second control line intersect at a flux control port location of the parametrically driven tunable coupler. In another aspect, the specified condition comprises a sum or difference of the one or more first frequency signals and the one or more second frequency signals that correspond to the pair of superconducting qubits, and the specified condition comprises a sum or difference of the one or more first frequency signals, the one or more second frequency signals and a dipole drive signal that correspond to the single superconducting qubit. In another aspect, the pair of superconducting qubits comprises Q!/(2!*(Q−2)!) pairwise combinations for the set of three or more superconducting qubits where Q is a number of superconducting qubits in the set of three or more superconducting qubits.

Circuits can be implemented with, but are not limited to, single or combinations of discrete electrical and electronic components, integrated circuits, semiconductor devices, analog devices, digital devices, etc. Elements can be coupled together using any type of suitable direct or indirect connection between the elements including, but not limited to, wires, pathways, channels, vias, electromagnetic induction, electrostatic charges, optical links, wireless communication links, etc.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this disclosure pertains. All publications and patent applications are herein incorporated by reference to the same extent as if each individual publication or patent application was specifically and individually indicated to be incorporated by reference.

In the specification, reference may be made to the spatial relationships between various components and to the spatial orientation of various aspects of components as the devices are depicted in the attached drawings. However, as will be recognized by those skilled in the art after a complete reading of the present application, the devices, members, apparatuses, etc. described herein may be positioned in any desired orientation. Thus, the use of terms such as “above,” “below,” “upper,” “lower,” or other like terms to describe a spatial relationship between various components or to describe the spatial orientation of aspects of such components should be understood to describe a relative relationship between the components or a spatial orientation of aspects of such components, respectively, as the device described herein may be oriented in any desired direction.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. In embodiments of any of the compositions and methods provided herein, “comprising” may be replaced with “consisting essentially of” or “consisting of.” As used herein, the phrase “consisting essentially of” requires the specified integer(s) or steps as well as those that do not materially affect the character or function of the claimed invention. As used herein, the term “consisting” is used to indicate the presence of the recited integer (e.g., a feature, an element, a characteristic, a property, a method/process step, or a limitation) or group of integers (e.g., feature(s), element(s), characteristic(s), property(ies), method/process(s) steps, or limitation(s)) only.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

As used herein, words of approximation such as, without limitation, “about,” “substantial” or “substantially” refers to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skill in the art recognize the modified feature as still having the required characteristics and capabilities of the unmodified feature. In general, but subject to the preceding discussion, a numerical value herein that is modified by a word of approximation such as “about” may vary from the stated value by at least ±1, 2, 3, 4, 5, 6, 7, 10, 12 or 15%.

All of the devices and/or methods disclosed and claimed herein can be made and executed without undue experimentation in light of the present disclosure. While the devices and/or methods of this disclosure have been described in terms of particular embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope, and concept of the invention as defined by the appended claims.

Furthermore, no limitations are intended to the details of construction or design herein shown, other than as described in the claims below. It is therefore evident that the particular embodiments disclosed above may be altered or modified and all such variations are considered within the scope and spirit of the disclosure. Accordingly, the protection sought herein is as set forth in the claims below.

Modifications, additions, or omissions may be made to the systems and apparatuses described herein without departing from the scope of the invention. The components of the systems and apparatuses may be integrated or separated. Moreover, the operations of the systems and apparatuses may be performed by more, fewer, or other components.

The methods may include more, fewer, or other steps. Additionally, steps may be performed in any suitable order.

To aid the Patent Office, and any readers of any patent issued on this application in interpreting the claims appended hereto, applicants wish to note that they do not intend any of the appended claims to invoke 35 U.S.C. § 112(f) as it exists on the date of filing hereof unless the words “means for” or “step for” are explicitly used in the particular claim.

### REFERENCES

[1] Y. Y. Gao, B. J. Lester, Y. Zhang, C. Wang, S. Rosenblum, L. Frunzio, L. Jiang, S. M. Girvin, R. J. Schoelkopf, Programmable Interface between Two Microwave Quantum Memories, Physical Review X 8, 021073 (2018) DOI: 10.1103/PhsRevX.8.021073.
[2] C. Zhou, P. Lu, M. Praquin, T-C Chien, R. Kaufman, X Cao, M. Xia, R. S. K. Mong, W. Pfaff, D. Pekker, M. Hatridge, A modular quantum computer based on a quantum state router, Research Square (2022) DOI: 10.21203/rs.3.rs-1547284/v1.

What is claimed is:

1. A controller for a set of superconducting qubits comprising:
a parametrically driven tunable coupler coupled to each superconducting qubit in the set of superconducting qubits comprising three or more superconducting qubits;
a magnetic flux pump coupled to the parametrically driven tunable coupler;
a first control line coupled to the magnetic flux pump;
a second control line coupled to the magnetic flux pump; and
wherein the parametrically driven tunable coupler creates a parametric single superconducting qubit drive for a single superconducting qubit within the set of superconducting qubits or a parametric resonant interaction between a pair of superconducting qubits within the set of superconducting qubits when one or more first frequency signals on the first control line and one or more second frequency signals on the second control line satisfy a specified condition.

2. The controller of claim 1, further comprising a readout resonator coupled to each superconducting qubit in the set of superconducting qubits.

3. The controller of claim 1, wherein each superconducting qubit in the set of superconducting qubits is configured to respond to a specified frequency from the parametrically driven tunable coupler.

4. The controller of claim 1, wherein the set of superconducting qubits are arranged around each parametrically driven tunable coupler.

5. The controller of claim 1, wherein the parametrically driven tunable coupler includes a superconducting quantum interface device (SQUID).

6. The controller of claim 1, wherein the first control line and the second control line intersect at a flux control port location of the parametrically driven tunable coupler.

7. The controller of claim 1, wherein:
the specified condition comprises a sum or difference of the one or more first frequency signals and the one or more second frequency signals that correspond to the pair of superconducting qubits; and
the specified condition comprises a sum or difference of the one or more first frequency signals, the one or more second frequency signals and a dipole drive signal that correspond to the single superconducting qubit.

8. The controller of claim 1, wherein the pair of superconducting qubits comprises Q!/((2!*(Q−2)!))) pairwise combinations for the set of three or more superconducting qubits where Q is a number of superconducting qubits in the set of three or more superconducting qubits.

9. The controller of claim 1, wherein:
the set of superconducting qubits, the parametrically driven tunable coupler and the magnetic flux pump are disposed on a first chip;
the first control line and the second control line are disposed on a second chip; and
the first chip and the second chip are bonded together in a flip-chip configuration.

10. A quantum processor comprising:
an array of superconducting qubits arranged in sets of three or more superconducting qubits;
a controller coupled to each set of three or more superconducting qubits, the controller comprising:
a parametrically driven tunable coupler coupled to each superconducting qubit in the set of three or more superconducting qubits,
a magnetic flux pump coupled to the parametrically driven tunable coupler,
a first control line coupled to the magnetic flux pump, and
a second control line coupled to the magnetic flux pump; and
wherein the parametrically driven tunable coupler creates a parametric single superconducting qubit drive for a single superconducting qubit within the set of three or more superconducting qubits or a parametric resonant interaction between a pair of superconducting qubits within the set of three or more superconducting qubits when one or more first frequency signals on the first control line and one or more second frequency signals on the second control line satisfy a specified condition.

11. The quantum processor of claim 10, wherein a number of superconducting qubits in the array of superconducting qubits scales at N×M while a total number of the first control lines and the second control lines scales at N+M.

12. The quantum processor of claim 10, further comprising a readout resonator coupled to each superconducting qubit in the set of three or more superconducting qubits.

13. The quantum processor of claim 10, wherein each superconducting qubit in the set of three or more superconducting qubits is configured to respond to a specified frequency from the parametrically driven tunable coupler.

14. The quantum processor of claim 10, wherein the parametrically driven tunable couplers are arranged in a square lattice, a rectangular lattice, an oblique lattice, a hexagonal lattice or a rhombic lattice with the three or more superconducting qubits arranged around each parametrically driven tunable coupler.

15. The quantum processor of claim 10, wherein the parametrically driven tunable coupler includes a superconducting quantum interface device (SQUID).

16. The quantum processor of claim 10, wherein the first control line and the second control line intersect at a flux control port location of the parametrically driven tunable coupler.

17. The quantum processor of claim 10, wherein:
the specified condition comprises a sum or difference of the one or more first frequency signals and the one or more second frequency signals that correspond to the pair of superconducting qubits; and
the specified condition comprises a sum or difference of the one or more first frequency signals, the one or more second frequency signals and a dipole drive signal that correspond to the single superconducting qubit.

18. The quantum processor of claim 10, wherein the pair of superconducting qubits comprises Q!/(2!*(Q−2)!) pairwise combinations for the set of three or more superconducting qubits where Q is a number of superconducting qubits in the set of three or more superconducting qubits.

19. The quantum processor of claim 10, wherein:
the set of superconducting qubits, the parametrically driven tunable coupler and the magnetic flux pump are disposed on a first chip;
the first control line and the second control line are disposed on a second chip; and
the first chip and the second chip are bonded together in a flip-chip configuration.

20. A method of controlling a set of superconducting qubits comprising:
providing a parametrically driven tunable coupler coupled to each superconducting qubit in the set of superconducting qubits comprising three or more superconducting qubits, a magnetic flux pump coupled to the parametrically driven tunable coupler, a first control line coupled to the magnetic flux pump, and a second control line coupled to the magnetic flux pump;
transmitting one or more first frequency signals on the first control line and one or more second frequency signals on the second control line; and
creating, using the parametrically driven tunable coupler, a parametric single superconducting qubit drive for a single superconducting qubit within the set of superconducting qubits or a parametric resonant interaction between a pair of superconducting qubits within the set of superconducting qubits when the one or more first frequency signals and the one or more second frequency signals satisfy a specified condition.

21. The method of claim 20, further comprising a readout resonator coupled to each superconducting qubit in the set of superconducting qubits.

22. The method of claim 20, wherein each superconducting qubit in the set of superconducting qubits is configured to respond to a specified frequency from the parametrically driven tunable coupler.

23. The method of claim 20, wherein the set of superconducting qubits are arranged around each parametrically driven tunable couple.

24. The method of claim 20, wherein the parametrically driven tunable coupler includes a superconducting quantum interface device (SQUID).

25. The method of claim 20, wherein the first control line and the second control line intersect at a flux control port location of the parametrically driven tunable coupler.

26. The method of claim 20, wherein:
the specified condition comprises a sum or difference of the one or more first frequency signals and the one or more second frequency signals that correspond to the pair of superconducting qubits; and
the specified condition comprises a sum or difference of the one or more first frequency signals, the one or more second frequency signals and a dipole drive signal that correspond to the single superconducting qubit.

27. The method of claim 20, wherein the pair of superconducting qubits comprises Q!/(2!*(Q−2)!) pairwise combinations for the set of three or more superconducting qubits where Q is a number of superconducting qubits in the set of three or more superconducting qubits.
